(19) United States
(12) Patent Application Publication
(10) Pub. No.: US 2022/0406694 A1
(43) Pub. Date: Dec. 22, 2022

(54) CONDUCTIVE METAL FRAME FOR A POWER ELECTRONIC MODULE AND ASSOCIATED MANUFACTURING PROCESS

(71) Applicants: SAFRAN, Paris (FR); SAFRAN ELECTRONICS & DEFENSE, Boulogne-Billancourt (FR)

(72) Inventors: Toni YOUSSEF, Moissy-Cramayel (FR); Stéphane Joseph AZZOPARDI, Moissy-Cramayel (FR); Thanh Long LE, Moissy-Cramayel (FR); Jean-Christophe RIOU, Moissy-Cramayel (FR); Nawres SRIDI-CONVERS, Moissy-Cramayel (FR)

(73) Assignees: SAFRAN, Paris (FR); SAFRAN ELECTRONICS & DEFENSE, Boulogne-Billancourt (FR)

(21) Appl. No.: 17/755,982

(22) PCT Filed: Nov. 12, 2020
(86) PCT No.: PCT/FR2020/052066

§ 371 Date: May 13, 2022

(30) Foreign Application Priority Data
Nov. 19, 2019 (FR) 1912900

(51) Int. Cl. H01L 23/495; H01L 21/48; H01L 21/56

(52) U.S. Cl. CPC H01L 23/49568; H01L 21/4842; H01L 21/56; H01L 23/49575; H01L 23/49537; H01L 21/4825; H01L 23/49524; H01L 23/49579

(57) ABSTRACT

A conductive metal frame for a power electronics module comprising at least first and second power semiconductor components each having upper and lower faces, connectors for linking these power semiconductor components to external electrical circuits and at least one radiator for expelling via the conductive metal frame the heat flow generated by the power semiconductor components, the conductive metal frame being characterized in that the connectors, the at least one radiator and the conductive metal frame forming a single three-dimensional part made of a single material on an inner surface of which the first and second power semiconductor components are intended to be attached by their lower faces and provision is made for a central folding line so that, once the conductive metal frame is folded on itself, enclosing the first and second power semiconductor components, it provides a double-sided cooling assembly.

### TECHNICAL FIELD

This invention relates to the general field of power conversion, particularly in the aerospace field where the thermal restrictions and the mass and volume restrictions can be severe and it specifically relates to a conductive metal frame (leadframe) of power electronics modules incorporating converters and required for the electrification of the propulsive and non-propulsive systems on board aircraft, in order to convert the electrical power of the main network (115 V AC, 230 V AC, 540 V DC . . . ) into various appropriate forms (AC/DC, DC/AC, AC/AC and DC/DC).

### PRIOR ART

FIG. 7 shows a conventional semi-conductive power stage 60 including two transistors of MOSFET type 62, 64 series-mounted between the supply voltages Vcc+ and Vcc−. Such a stage, with which a decoupling capacitor 66 and a current shunt 68 can be combined, is conventionally produced in the form of the conventional power electronics module, the superposition of layers of different materials forming this module 70 being schematically illustrated in FIG. 8, and including:
first and second power semiconductor components 72 (heat source),
a first metal interconnection interface 74 (soldered or sintered seal, filled adhesive) to attach the power semiconductor component onto a substrate,
a substrate generally composed of an electrical insulating ceramic 76 between two metal plates 76a, 76b, manufactured using various techniques (Direct Bonded Copper—DBC—, Active Metal Brazing—AMB—, Direct Bonded Aluminum—DBA—) and making it possible to produce the interconnections (connecting the semiconductors to one another and to the external electrical circuits) on the upper metal parts and the attachment to a baseplate via the lower metal part,
a soldered seal 78 often used as second interconnect interface to attach the substrate to a baseplate,
a conductive metal frame forming a baseplate 80, generally made of copper, aluminum or aluminum/silicon carbide composite, and which has the role of spreading the heat flow and ensuring the mechanical connection with a cooling system,
a heat interface material 82 makes it possible to reduce the contact thermal resistance between the baseplate and a cooling system to provide a better expulsion of the heat flow. This heat interface material can be rigid (solder, sintered joint etc.) or more generally flexible (thermal grease, silicon elastomer film, phase-change material etc.),
a cooling system 84, typically a finned air-cooling radiator, but a liquid cooling system can also be envisioned,
metal wires 86 providing the internal connection between the different components and connectors 88 (external connection) attached (by solders 90) to the metal plates 76a of the substrates to provide the electrical contacts with the external electrical circuits,
finally a box 92 serving as mechanical protection in the case of a plastic box or a diffusion and electromagnetic shielding barrier in the case of a metal box, the vacuum in the box being filled by an encapsulant insulator of silicone gel type 94.

However, this stacking of materials has several limitations, particularly for high-temperature applications (>175° C.): the first is the high thermal resistance (low thermal conductivity in the order of 2 W/mK) initially due to the thermal interface material (in the case of a flexible material) and to the nine layers of material existing between the power semiconductor and the coolant (or the air in contact with the radiator fins in the case of air cooling), the second is related to high-temperature instability, initially limited by the operating temperature of the thermal interface (thermal grease: 150° C.) incompatible with use at high temperatures, and the final limitation is the limited reliability of the assembly due to the thermal fatigue phenomenon resulting from the difference between the thermal expansion coefficients of the various materials. More particularly, if using rigid interface materials (the case of soldering or sintering), this fatigue is a source of crack propagation in the solder over the large surfaces, in particular between the substrate and the baseplate and between the baseplate and the radiator. The process for providing a good interface remains complex and the mechanical stresses are very high, thus limiting its thermomechanical reliability.

### SUMMARY OF THE INVENTION

This invention has the aim of palliating the aforementioned drawbacks by making provision for a power electronics module requiring a reduced number of manufacturing steps by comparison with conventional modules and which to do so includes a three-dimensional metal frame machined from a single piece and incorporating at least the cooler and the connections into the external electrical circuits.

These aims are achieved by a conductive metal frame for a power electronics module comprising at least first and second power semiconductor components each having upper and lower faces, connectors for linking these power semiconductor components to external electrical circuits and at least one radiator for expelling via the conductive metal frame the heat flow generated by the power semiconductor components, the conductive metal frame being characterized in that the connectors, the at least one radiator and the conductive metal frame form a single three-dimensional part made of a single material on an inner surface of which the first and second power semiconductor components are intended to be attached by their lower faces and in that it further includes a central folding line which, once the conductive metal frame is folded on itself, enclosing the first and second power semiconductor components, provides a double-sided cooling assembly.

Thus, by dispensing with the metallized ceramic, the different constituent polymers of the adhesive seals for bonding the box, the thermal interface material and the box itself, the use of the power module for temperatures greater than 200° C. becomes possible on condition that an encapsulant is chosen that can withstand the desired temperatures.

Preferably, the conductive metal frame can also include a metal comb with interdigitated fins intended to form a decoupling capacitor once the conductive metal frame is folded on itself or one or more metal leaves of predetermined section intended to form a current shunt.

Advantageously, it includes locating studs intended to be housed in locating holes once the conductive metal frame is folded on itself.

Preferably, it is thinned at the level of the central folding line.

Advantageously, the material of the conductive metal frame is chosen from among the following materials: aluminum, copper or gold.

The invention also relates to the power electronics module including a conductive metal frame as aforementioned.

The invention also relates to a process for manufacturing a power electronics module comprising at least first and second power semiconductor components each having upper and lower faces, connectors for linking these power semiconductor components to external electrical circuits and at least one radiator for expelling via a conductive metal frame the heat flow generated by the power semiconductor components, characterized in that it includes the following steps: manufacturing a three-dimensional conductive metal frame having a central folding line and including several geometrical structures each including a predetermined function, depositing a seal on predetermined spaces of an inner surface of the three-dimensional conductive metal frame to which the first and second power semiconductor components are intended to be attached, attaching the lower faces of the first and second power semiconductor components to a part of the predetermined spaces of the inner surface of the three-dimensional conductive metal frame, folding the three-dimensional conductive metal frame into two parts along the central folding line and attaching the upper faces of the first and second power semiconductor components on another part of the predetermined spaces of the inner surface of the three-dimensional conductive metal frame, such as to provide a double-sided cooling assembly, solidifying the seal and molding in an encapsulant formed of an electrically insulating material, and cutting off parts of the three-dimensional conductive metal frame which do not contribute any electrical, thermal or mechanical function to obtain the power electronics module.

Advantageously, the three-dimensional conductive metal frame is obtained by mechanical machining or metallic 3D printing.

Preferably, the step of depositing the seal is preceded by a step of electrical bonding of the inner surface of the three-dimensional conductive metal frame.

### BRIEF DESCRIPTION OF THE DRAWINGS

Other features and advantages of this invention will become more apparent from the description given below, with reference to the appended drawings which illustrate non-limiting exemplary embodiments thereof and wherein:

FIG. 1A is a perspective top view of a first exemplary embodiment of a conductive metal frame according to the invention,

FIG. 1B is a perspective bottom view of a first exemplary embodiment of a conductive metal frame according to the invention,

FIG. 2A shows a step of manufacturing of a power module including the conductive metal frame of the FIGS. 1A and 1B,

FIG. 2B shows a step of manufacturing of a power module including the conductive metal frame of the FIGS. 1A and 1B,

FIG. 2C shows a step of manufacturing of a power module including the conductive metal frame of the FIGS. 1A and 1B,

FIG. 2D shows a step of manufacturing of a power module including the conductive metal frame of the FIGS. 1A and 1B,

FIG. 2E shows a step of manufacturing of a power module including the conductive metal frame of the FIGS. 1A and 1B,

FIG. 2F shows a step of manufacturing of a power module including the conductive metal frame of the FIGS. 1A and 1B,

FIG. 3 shows before encapsulation the incorporation of a decoupling capacitor onto the conductive metal frame of the invention,

FIG. 4 shows before encapsulation the incorporation of a current shunt onto the conductive metal frame of the invention,

FIG. 5 is a perspective bottom view of a second exemplary embodiment of a conductive metal frame according to the invention,

FIG. 6A shows a step of manufacturing of a power module including the conductive metal frame of FIG. 5,

FIG. 6B shows a step of manufacturing of a power module including the conductive metal frame of FIG. 5,

FIG. 6C shows a step of manufacturing of a power module including the conductive metal frame of FIG. 5,

FIG. 6D shows a step of manufacturing of a power module including the conductive metal frame of FIG. 5,

FIG. 6E shows a step of manufacturing of a power module including the conductive metal frame of FIG. 5,

FIG. 6F shows a step of manufacturing of a power module including the conductive metal frame of FIG. 5,

FIG. 6G shows a step of manufacturing of a power module including the conductive metal frame of FIG. 5,

FIG. 7 shows a conventional one-stage semiconductor power module including two transistors of MOSFET type, and

FIG. 8 illustrates in section view and schematically the superposition of layers of the different materials forming a conventional semiconductor power module.

### DESCRIPTION OF THE EMBODIMENTS

The subject of this invention is a three-dimensional conductive metal frame, an upper (or outer) face of which includes at least one radiator and connectors for linking to outer circuits, the power semiconductor components being conventionally attached by soldering or sintering by means of seals on a lower (or inner) face of this frame and the assembly thus formed is protected in a coating material.

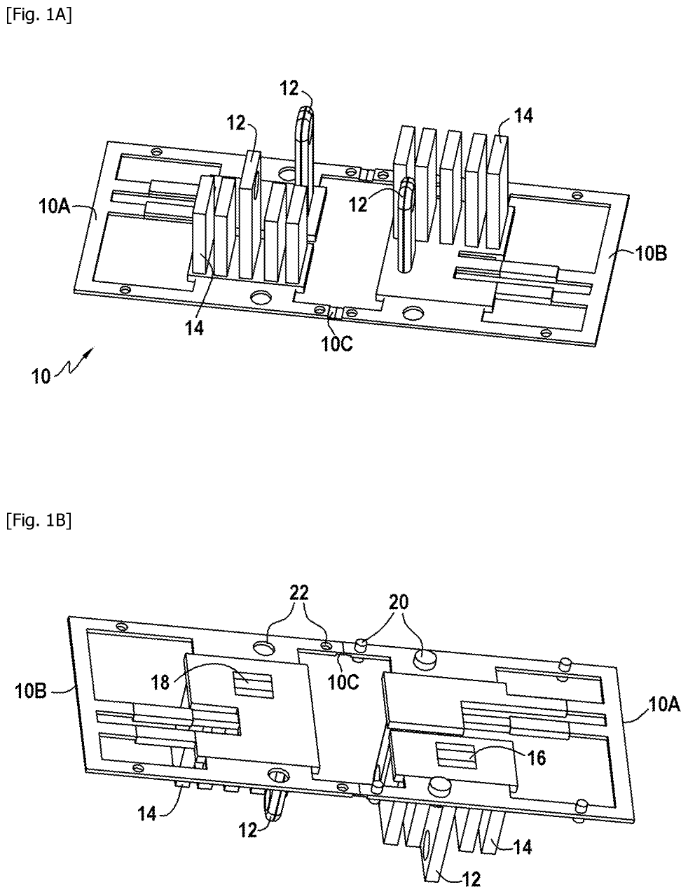

FIGS. 1A and 1B show, in perspective top and bottom view respectively, this conductive metal frame 10 which forms with the linking connectors 12 and the two radiators 14 mounted on its upper face a part cut from a single solid made of a single material on the lower face of which the first 16 and second 18 power semiconductor components are attached by a seal. This conductive metal frame is therefore a three-dimensional object which extends vertically from a rectangular base separated into two quasi-symmetrical parts 10A, 10B each supporting one radiator 14 and at least one linking connector 12, the part 10C of the conductive metal frame providing the join between these two parts being thinned to form a central folding line of this conductive metal frame. The radiator is advantageously an air-cooling finned radiator but a water cooler provided with channels or micro-channels, or else any other more complex geometrical form, can also be envisioned.

The base of the conductive metal frame preferably includes on its periphery and on one of the two parts (for example 10A) locating studs 20 intended to be housed in locating holes 22 disposed on the other of the two parts (in this case 10B), once the conductive metal frame has been folded on itself, as will be explained further on.

The conductive metal frame can advantageously be made by any known metal-based additive manufacturing process, for example of SLM (Selective Laser Melting) type, made of one and the same conductive material such as aluminum, copper or an aluminum/silicon carbide composite for example, or else by a mechanical machining of a raw block of material.

This single-material production limits the residual mechanical stresses and reduces the time of assembly and production of the power module, as will be described further on. The radiators can thus have a complex geometry and a reduced mass which makes it possible to increase the power density of the converters.

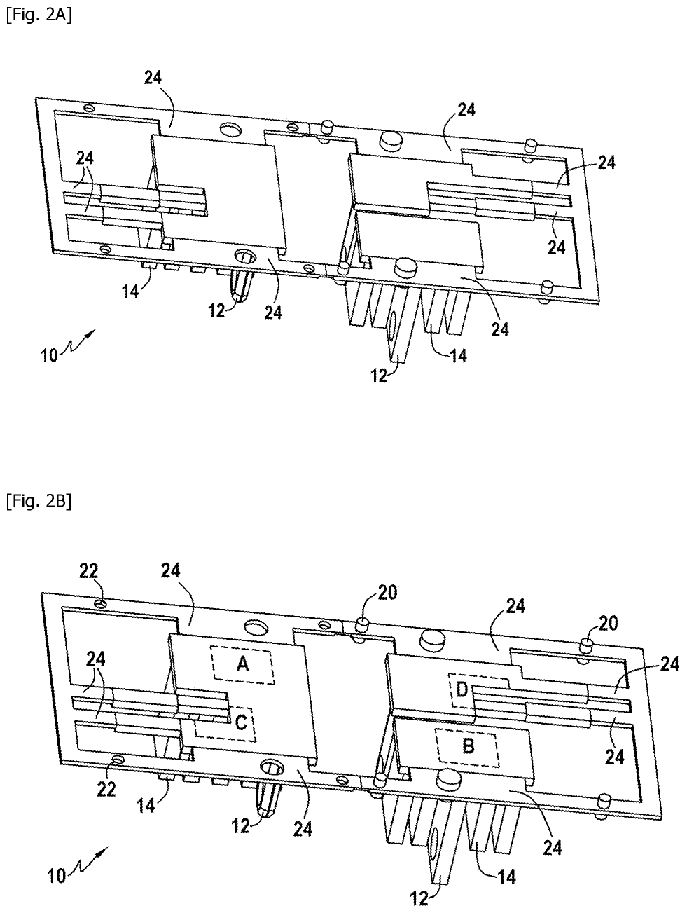

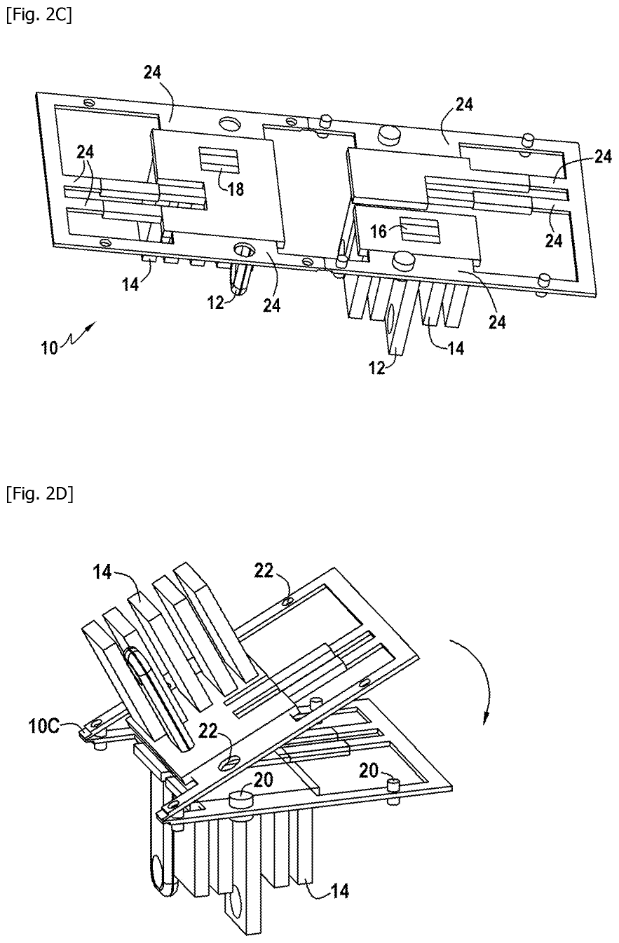

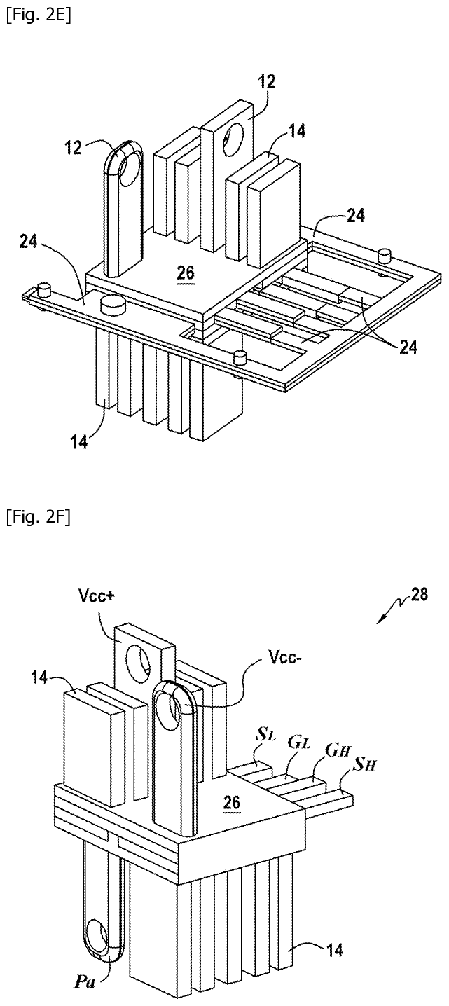

FIGS. 2A to 2F show the different steps of manufacturing of a power module including the aforementioned conductive metal frame. This process employs only four materials which advantageously have equivalent thermal expansion coefficients: the metal of the conductive metal frame (Al, Cu, etc.), the material of the power semiconductor components (or chips) (Si, SiC, etc.), the seal (obtained by SnAgCu etc. soldering, or Ag, Cu, etc. sintering) and the material encapsulating the assembly thus formed.

The first step (FIG. 2A) consists in the mechanical machining or metal 3D printing by additive manufacturing process of the conductive metal frame 10. As mentioned previously, this frame includes several geometrical structures each corresponding to a very specific function (radiators 14, connectors 12 and possible other passive components as will be described further on). These three-dimensional structures, associated with specific functions, are therefore made of one and the same material and linked to one another or to the periphery of the conductive metal frame by bridges 24 which will be cut off at the end of the process.

The second step (FIG. 2B) consists in producing on the lower base of the conductive metal frame 10 the seal (solder, sintered seal, adhesive with metallic fillers etc.) which will provide the attachment of the power semiconductor components at predetermined positions (areas A, B, C and D) of the conductive metal frame, for example with a printing screen or else an automatic tooling (of Pick & place machine type). In one or the other case, the studs 20 or the holes 22 will define locating references for the machine or the printing screen (both not illustrated).

Note that this second step can be preceded by a step of electrical bonding (Ni/Au for example) of the areas intended to house the power semiconductor components to facilitate the attachment of these components.

The third step (FIG. 2C) consists in positioning the lower face of the power semiconductor components 16, 18 above the corresponding seals of the areas A and B with a mechanical tooling or else an automatic machine (also of Pick & Place type). Note that when the power semiconductor component is a MOSFET transistor, the face of the MOSFET positioned on the seal corresponds to the drain of the transistor, the source and the gate being on the upper face of the component left free in this step.

In a fourth step (FIG. 2D), the conductive metal frame is folded on itself (with accuracy by sliding the studs 20 into the holes 22) at its folding line 10C in order to then be positioned above the power semiconductor components. This folding action allows, thanks to the seal pre-deposited in the areas C and D in the second step to provide the fastening of the upper face of the power semiconductor components and thus have an assembly with a radiator on both faces, i.e. double-sided cooling.

When the power semiconductor component is a MOSFET transistor, it is the face of the MOSFET corresponding to the source and to the gate left free in the preceding step which is now positioned on the seal. The folding also provides the connection of the connectors if necessary.

In a fifth step (FIG. 2E) and according to the nature of the seal, the assembly is solidified at high temperature to be able to perform the sintering, or put in a furnace to solidify the solder, then it is partially molded in a hard encapsulant 26 (or an electrical insulator of Parylene type for example) in order to protect the semiconductor components from the outside environment and reduce the phenomena of partial discharge into the air.

Finally in a last step (FIG. 2F), the parts of the bridges 24 (see the preceding figure) of the conductive metal frame which are used to retain the various geometrical structures at the base of the frame, but which have no electrical, or thermal, or mechanical function, are cut off to form the desired power module 28 which therefore has cooling on both these faces and the conventional connections and links to external electrical circuits of such a power module, namely: the terminals Vcc+ and Vcc−, the two source and gate terminals of the two transistors Sh, Gh and SI, GI and the phase terminal Pa of the module.

As indicated previously, the geometrical structures can be various and also include passive components.

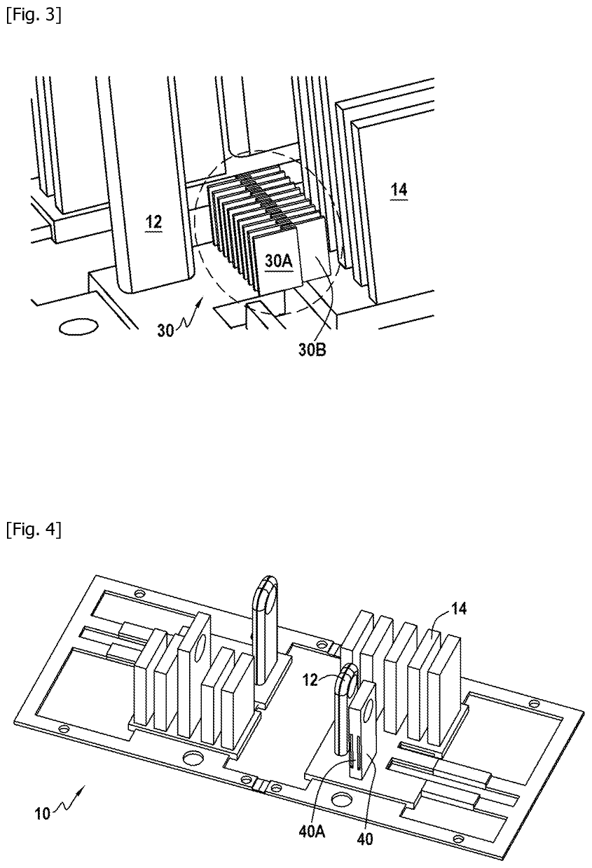

FIG. 3 shows a first example of incorporation of a passive component onto the conductive metal frame. Specifically, with the structure cut from a single solid of the invention, it is possible to add a decoupling capacitor between the electrical supply terminals Vcc+ and Vcc−, as close as possible to the power semiconductor components. This makes it possible to reduce the effect of interfering loop inductance, constitutes a sufficient energy reserve to feed the load, suppresses the high-frequency harmonics toward the lowest electrical potential and therefore increases the electromagnetic immunity of the circuit. More precisely, this filtering capacitor is produced in the form of a metal comb 30 with interdigitated fins 30A, 30B alternately on a part of the frame at the potential Vcc+ and on another part of the frame at the potential Vcc−. The capacitance function of this capacitor will be obtained by adding between the fins forming the plates of this capacitor a dielectric material which can be the encapsulant material defined previously or another type of material.

In the same way, FIG. 4 shows a second possible example of incorporation of a passive component, in this case a current shunt 40 (a simple electrical resistance of very low value which makes it possible to measure the electrical current passing through it) produced in the form of one or more metal leaves 40A of predetermined section. The particular geometry of this current shunt will make it possible to give it a known resistance value with accuracy.

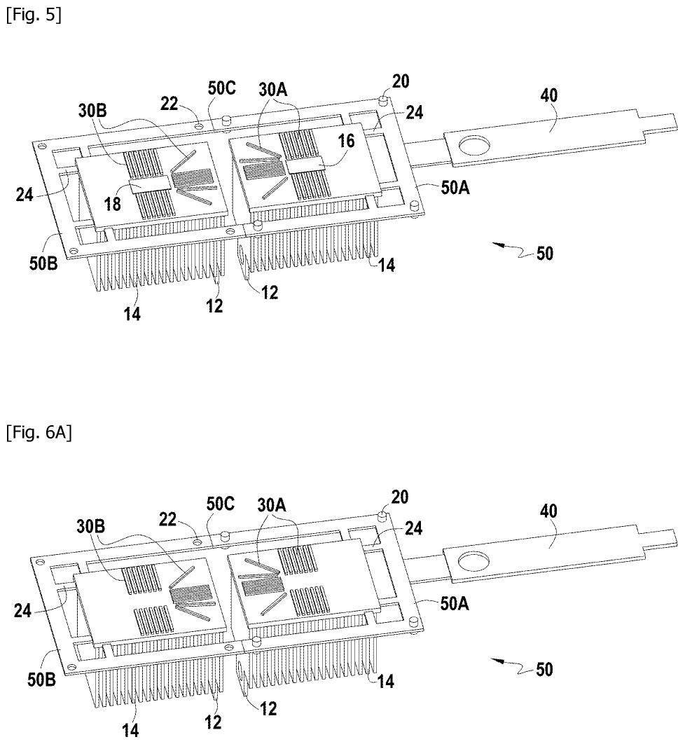

FIG. 5 is a perspective bottom view of a second exemplary embodiment of a conductive metal frame 50 according to the invention. It shows a conductive metal frame with two symmetrical parts 50A, 50B separated by a central folding line 50C, these two parts being contained in a peripheral frame bearing, for one of them, (for example the area 50A) of the locating studs 20 and for the other the locating holes 22 (in this case 50B), these studs being intended to be received in these holes once the conductive metal frame is folded on itself. Each of these two parts supports on its outer face a radiator 14 and a connector 12 and on its inner face one of the two plates 30A, 30B of a filtering capacitor 30, these different elements being linked to the periphery of the conductive metal frame by linking bridges 24. These two plates are here formed of a plurality of fins distributed around the spaces intended to house the first 16 and the second 18 power semiconductor components. Finally, a current shunt 40 formed by a metal leaf or tab of predetermined section and made with the other geometrical structures (radiators, connectors and capacitor) out of one and the same material by additive manufacturing process or mechanical machining, extends toward the outside of the conductive metal frame from one of its two parts (in this case the part 50A).

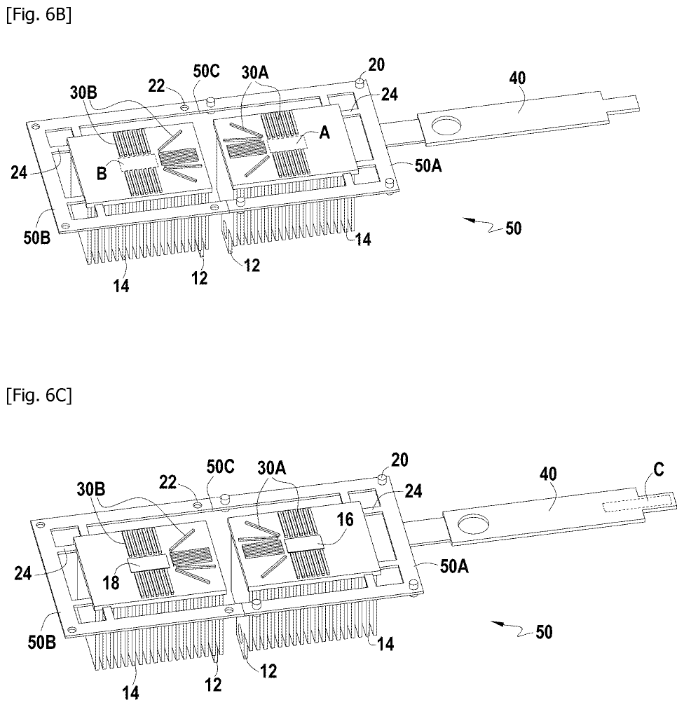

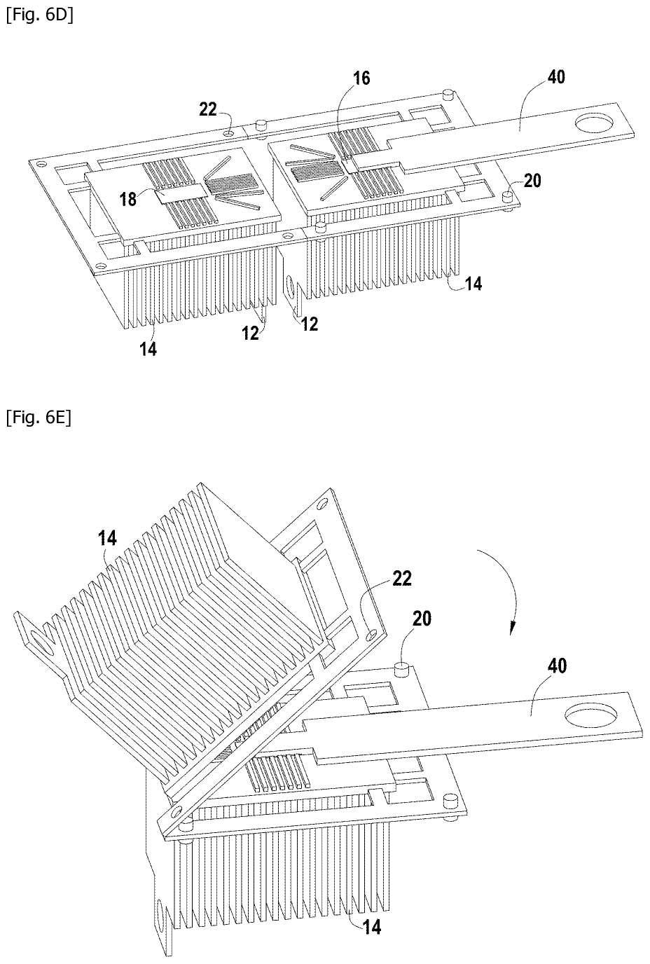

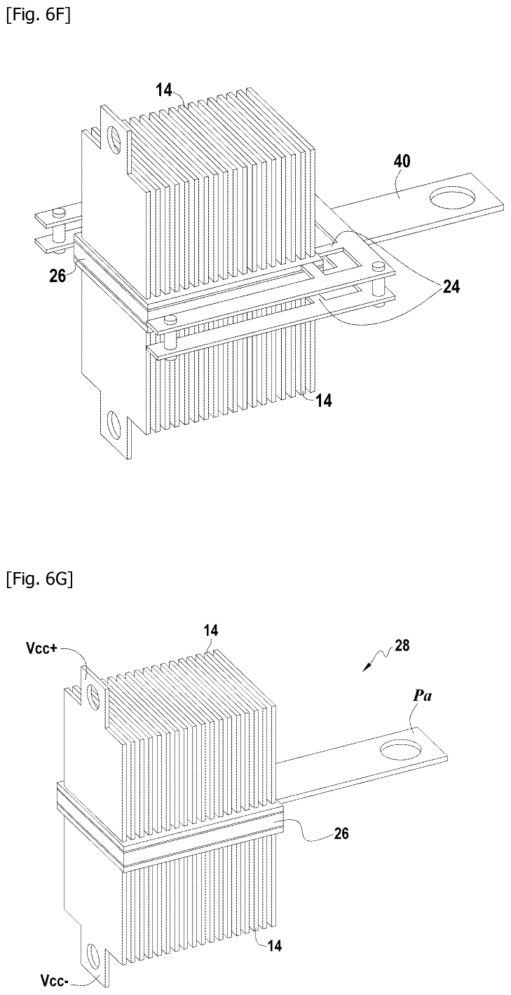

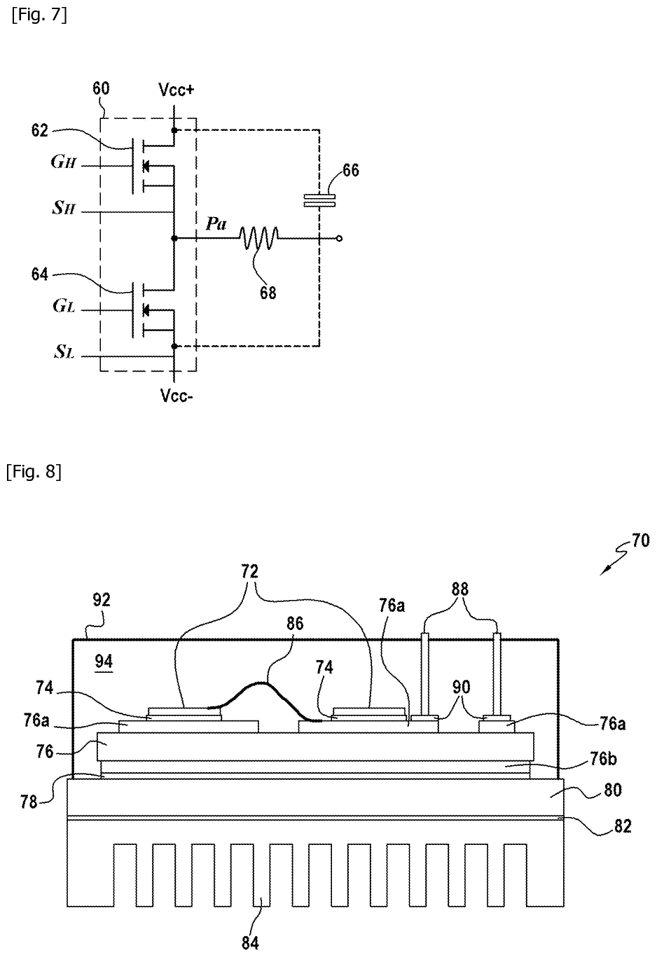

FIGS. 6A to 6G show the different steps in the manufacturing of a power module including the conductive metal frame of this second exemplary embodiment.

The first step (FIG. 6A) consists in the manufacturing of the conductive metal frame now containing four types of geometrical structures: radiators, connectors, a capacitor and a shunt. The capacitor is disposed on the inner face of the conductive metal frame, the radiators (liquid or air in this case) and the connectors on the outer face, the current shunt extending the frame having both an inner face and an outer face.

The second step (FIG. 6B) consists in making the seal (solder, sintered seal or filled adhesive) which will provide the attachment of the power semiconductor components at a predetermined position (areas A and B) of the conductive metal frame. However, in this embodiment, the fins of the capacitor being arranged all around the power semiconductor components prevent the deposition of this seal with a printing screen, only the use of automatic tooling can be envisioned with this configuration.

The third step (FIG. 6C) consists as previously in positioning the lower face of the power semiconductor components above the seals with a mechanical tooling or else an automatic precision machine.

In a fourth step (FIG. 6C), another seal is deposited on the metal tab 40 both on its upper face (area C) and on its lower face (the hidden face) before this metal tab is folded to position it above one of the two power semiconductor components in a fifth step (FIG. 6D).

The conductive metal frame is then in turn, in a sixth step (FIG. 6E), folded on itself with accuracy (by the engagement of the studs 20 in the corresponding holes 22) in order to provide the fastening of the upper face of the power semiconductor components and to have a double-sided cooling assembly. In this configuration, each power semiconductor component is thus sandwiched between two seals, one of which is in contact with the metal tab 40.

In a seventh step (FIG. 6F) the seal is solidified at high temperature or heating according to its nature.

The deposition of an electrically insulating material 26 (of hard coating, Parylene etc. type) on a part of the assembly thus made in an eight step (FIG. 6F) completes the electrical insulation and embodies the capacitance between the two plates of the capacitor that the folding has interdigitated.

Finally a last step (FIG. 6G) consists in cutting off the part of the conductive metal frame (see bridges 24 in the preceding figure) which has served to retain the various geometrical structures but which having neither electrical, thermal, or mechanical function has now become pointless, to obtain the desired power module 28 which therefore has cooling on both these faces and the connections and conventional links to external circuits of such a power module, namely: the supply terminals Vcc+ and Vcc− and the phase terminal Pa (for the sake of simplicity the source and gate terminals which will exit in the same plane as the phase terminal Pa and on the same side as Vcc+ and Vcc−, are not shown). Regardless of the circumstances, the inputs are available on one side of the module and the output on another side of the module.

It will be noted that in one or the other of these two aforementioned embodiments, in order to convey the signal (low current, low voltage) to the power semiconductor components, it is possible to deposit a fine conductive layer on an electrical insulation formed by a deposition of an electrical insulator (of Parylene type for example) on the inner face of the conductive metal frame. This technique is conventionally used during the manufacturing of Printed Circuit Boards (PCB) using Insulated Metal Substrate (SMI) technology.

Note also that if, in the context of specific applications, there is a need to use power semiconductor components of different thicknesses, machining from a single solid or additive manufacturing will easily make it possible to compensate for this range of thicknesses.

By comparison with the prior art, the process of the invention makes it possible to generate in a single step all the constituent passive components of a power module to which the active power elements must conventionally be attached, using seals and thus reducing the number of manufacturing steps, improving the heat dissipation interface and increasing reliability via the reduction of the number of interfaces potentially subject to thermo-mechanical rupture.

With the invention, the number of materials and interfaces is reduced; in particular the metallized ceramic substrate, the thermal interface material and the fasteners of the connectors and boxes are dispensed with, thus leading to a reduction in the weight and volume of the power electronics module. This allows the improvement of the reliability of the assembly and a reduction of its thermal resistance. In addition, the production of radiators located on the conductive metal frame vis-à-vis hotspots (the power semiconductor components) allows efficient management of thermal dynamics.

Thus, a power module based on a three-dimensional conductive metal frame in accordance with the invention allows, on the one hand, the production of a complex assembly with various functions: current sensors, external connections, cooling system (liquid, air etc.), decoupling capacitor on the DC bus or else near the power semiconductor component, etc., and on the other hand the obtainment of an assembly with low residual stresses due to the presence of only two thermal profiles during the assembly, namely: the attachment of chips (by soldering or sintering) and the encapsulation which will preferably be done in a vacuum.

1. A conductive metal frame for a power electronics module comprising at least first and second power semiconductor components each having upper and lower faces, connectors for linking these power semiconductor components to external electrical circuits and at least one radiator for expelling via the conductive metal frame the heat flow generated by the power semiconductor components, the conductive metal frame being that wherein the connectors, the at least one radiator and the conductive metal frame form a single three-dimensional part made of a single material on an inner surface of which the first and second power semiconductor components are intended to be attached by their lower faces and in that it further includes a central folding line which, once the conductive metal frame is folded on itself, enclosing the first and second power semiconductor components, provides a double-sided cooling assembly.

2. The conductive metal frame as claimed in claim 1, further including a metal comb with interdigitated fins intended to form a filtering capacitor once the conductive metal frame is folded on itself.

3. The conductive metal frame as claimed in claim 1, further including one or more metal leaves of determined section intended to form a current shunt.

4. The conductive metal frame as claimed in claim 1, further including locating studs intended to be housed in locating holes once the conductive metal frame is folded on itself.

5. The conductive metal frame as claimed in claim 1, wherein the conductive metal is thinned at the level of the central folding line.

6. The conductive metal frame as claimed in claim 1, wherein the material of the conductive metal frame is chosen from among the following materials: aluminum, copper or gold.

7. A power electronics module including a conductive metal frame as claimed in claim 1.

8. A process for manufacturing a power electronics module comprising at least first and second power semiconductor components each having upper and lower faces, connectors for linking these power semiconductor components to external electrical circuits and at least one radiator for expelling via a conductive metal frame the heat flow generated by the power semiconductor components, the process including: manufacturing a three-dimensional conductive metal frame having a central folding line and including several geometrical structures each including a predetermined function, depositing a seal on predetermined spaces of an inner surface of the three-dimensional conductive metal frame to which the first and second power semiconductor components are intended to be attached, attaching the lower faces of the first and second power semiconductor components to a part of the predetermined spaces of the inner surface of the three-dimensional conductive metal frame, folding the three-dimensional conductive metal frame into two parts along the central folding line and attaching the upper faces of the first and second power semiconductor components on another part of the predetermined spaces of the inner surface of the three-dimensional conductive metal frame, such as to provide a double-sided cooling assembly, solidifying the seal and molding in an encapsulant formed of an electrically insulating material, and cutting off parts of the three-dimensional conductive metal frame which do not contribute any electrical, thermal or mechanical function to obtain the power electronics module.

9. The process as claimed in claim 7, wherein the three-dimensional conductive metal frame is obtained by mechanical machining or metal 3D printing.

10. The process as claimed in claim 7, wherein depositing the seal is preceded by electrical bonding of the inner surface of the three-dimensional conductive metal frame.
